(19) United States
(12) Patent Application Publication
(10) Pub. No.: US 2025/0107281 A1
(43) Pub. Date: Mar. 27, 2025

(54) MICRO LED AND MICRO LED DISPLAY PANEL

(71) Applicant: JADE BIRD DISPLAY (SHANGHAI) LIMITED, SHANGHAI (CN)

(72) Inventors: Zhichen GU, Shanghai (CN); Weisin TAN, Shanghai (CN)

(21) Appl. No.: 18/894,019

(22) Filed: Sep. 24, 2024

(30) Foreign Application Priority Data
Sep. 26, 2023 (WO) PCT/CN2023/121446

(51) Int. Cl. H01L 33/20; H01L 25/16

(52) U.S. Cl. CPC H10H 20/819; H01L 25/167

(57) ABSTRACT

A micro LED includes: a bonding layer; a P-N structure formed on the bonding layer, wherein the P-N structure includes a first type semiconductor layer, a light emitting layer formed on the first type semiconductor layer, and a second type semiconductor layer formed on the light emitting layer; and a top conductive layer formed on the P-N structure, wherein a top surface of the micro LED is a curved surface.

### CROSS-REFERENCE TO RELATED APPLICATIONS

The present disclosure claims the benefits of priority to PCT Application No. PCT/CN2023/121446, filed on Sep. 26, 2023, which is incorporated herein by reference in its entirety.

### TECHNICAL FIELD

The present disclosure generally relates to micro LED manufacturing technology, and more particularly, to a micro LED and a micro LED display panel.

### BACKGROUND

Inorganic micro pixel light emitting diodes, also referred to as micro light emitting diodes, micro LEDs, or u-LEDs, become more important since they are used in various applications including self-emissive micro-displays, visible light communications, and optogenetics. The micro LEDs have higher output performance than conventional LEDs because of better strain relaxation, improved light extraction efficiency, and uniform current spreading. Compared with conventional LEDs, the micro LEDs also exhibit several advantages, such as improved thermal effects, faster response rate, larger working temperature range, higher resolution, wider color gamut, higher contrast, lower power consumption, and operability at higher current density.

A micro LED display panel is manufactured by integrating an array of thousands or even millions of micro LEDs with an integrated circuit (IC) backplane. Each pixel of the micro LED display panel is formed by one or more micro LEDs. The micro LED display panel can be a mono-color or multi-color panel. In particular, for a multi-color LED panel, each pixel may further include multiple sub-pixels respectively formed by multiple micro LEDs, each of which corresponds to a different color. For example, three micro LEDs respectively corresponding to red, green, and blue colors may be superimposed to form one pixel. The different colors can be mixed to produce a broad array of colors.

Current micro LED technology faces several challenges, for example, improving light emission efficiency.

### SUMMARY OF THE DISCLOSURE

Embodiments of the present disclosure provide a micro LED. The micro LED includes: a bonding layer; a P-N structure formed on the bonding layer, wherein the P-N structure includes a first type semiconductor layer, a light emitting layer formed on the first type semiconductor layer, and a second type semiconductor layer formed on the light emitting layer; and a top conductive layer formed on the P-N structure, wherein a top surface of the micro LED is a curved surface.

Embodiments of the present disclosure also provide a micro LED display panel. The micro LED display panel includes an integrated circuit (IC) backplane including a bottom pad array, the bottom pad array comprising a plurality of bottom pads; and a micro LED array formed on the IC backplane, the micro LED array including a plurality of the micro LEDs of the present disclosure; wherein one micro LED of the plurality of micro LEDs is electrically connected with one bottom pad of the plurality of bottom pads.

### BRIEF DESCRIPTION OF THE DRAWINGS

Embodiments and various aspects of the present disclosure are illustrated in the following detailed description and the accompanying figures. Various features shown in the figures are not drawn to scale.

FIG. 1 illustrates a structural diagram showing an exemplary micro LED, according to some embodiments of the present disclosure.

FIG. 2 illustrates a structural diagram showing a variant of the micro LED shown in FIG. 1, according to some embodiments of the present disclosure.

FIG. 3 illustrates a structural diagram showing another exemplary micro LED, according to some embodiments of the present disclosure.

FIG. 4 illustrates a structural diagram showing a variant of the micro LED shown in FIG. 3, according to some embodiments of the present disclosure.

FIG. 5 illustrates a structural diagram showing another variant of the micro LED shown in FIG. 3, according to some embodiments of the present disclosure.

FIG. 6 illustrates a structural diagram showing another variant of the micro LED shown in FIG. 3, according to some embodiments of the present disclosure.

FIG. 7 illustrates a structural diagram showing another exemplary micro LED, according to some embodiments of the present disclosure.

FIG. 8 illustrates a structural diagram showing another exemplary micro LED, according to some embodiments of the present disclosure.

FIG. 9 illustrates a structural diagram showing a variant of the micro LED shown in FIG. 8, according to some embodiments of the present disclosure.

FIG. 10 illustrates a structural diagram showing a top view of an exemplary micro LED display panel, according to some embodiments of the present disclosure.

### DETAILED DESCRIPTION

Reference will now be made in detail to exemplary embodiments, examples of which are illustrated in the accompanying drawings. The following description refers to the accompanying drawings in which the same numbers in different drawings represent the same or similar elements unless otherwise represented. The implementations set forth in the following description of exemplary embodiments do not represent all implementations consistent with the invention. Instead, they are merely examples of apparatuses and methods consistent with aspects related to the invention as recited in the appended claims. Particular aspects of the present disclosure are described in greater detail below. The terms and definitions provided herein control, if in conflict with terms and/or definitions incorporated by reference.

In order to improve light emitting efficiency, embodiments of the present disclosure provide micro LEDs including, among other features, a curved top surface.

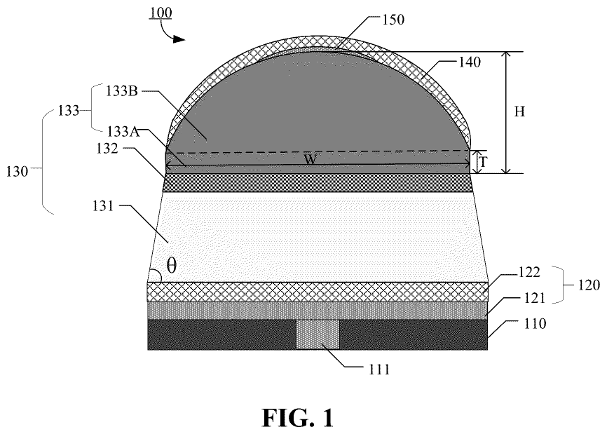

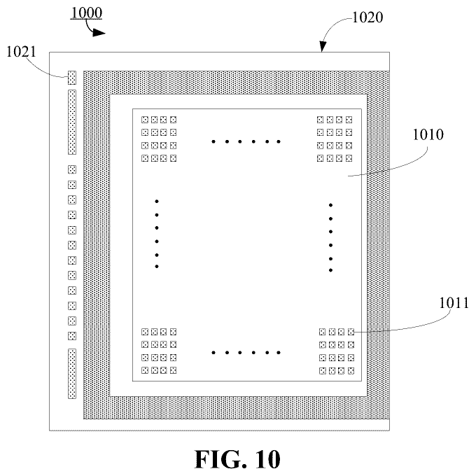

FIGS. 1-9 illustrate various features and variations of micro LEDs having a curved top surface, and FIG. 10 illustrates a micro displaying panel incorporating such micro LEDs.

FIG. 1 illustrates a structural diagram showing an exemplary micro LED 100, according to some embodiments of the present disclosure. As shown in FIG. 1, micro LED 100 includes a P-N structure 130 provided on an IC backplane 110, and a bonding layer 120 provided between P-N structure 130 and IC backplane 110. P-N structure 130 includes a first type semiconductor layer 131, a light emitting layer 132 formed on first type semiconductor layer 131, and a second type semiconductor layer 133 formed on light emitting layer 132. Micro LED 100 further includes a top conductive layer 140 formed on a top surface of P-N structure 130. A top surface of micro LED 100 is a curved surface, for example, a dome. In this example, the top surface of P-N structure 130 is a curved surface, and second type semiconductor layer 133 has a spherical cap structure. The spherical cap structure of the micro LED 100 can increase light extraction efficiency and improve beam angle performance.

In some embodiments, top conductive layer 140 is a TCO (transparent conductive oxide) layer, for example, an ITO (Indium Tin Oxide) layer, an AZO (Antimony doped Zinc Oxide) layer, an ATO (Antimony doped Tin Oxide) layer, an FTO (Fluorine doped Tin Oxide) layer, a CdO (Cadmium Oxide) layer, or a GZO (Gallium doped Zinc Oxide).

In some embodiments, second type semiconductor layer 133 further includes a base portion 133A formed on light emitting layer 132, and a curved portion 133B formed on base portion 133A. Base portion 133A and curved portion 133B are an integrated structure. A sidewall of base portion 133A is vertical. Curved portion 133B has a curved surface. In some embodiments, a height H of second type semiconductor layer 133 is less than a half of a width W of second type semiconductor layer 133. In some embodiments, height H is in a range of 1/4 to 1/2 of width W of second type semiconductor layer 133. In some embodiments, a thickness T of base portion 133A is less than 50 nm. Base portion 133A is configured for light extraction efficiency (LEE) optimization design, and a thickness of base portion 133A can be adjusted according to practical design.

Still referring to FIG. 1, in this example, first type semiconductor layer 131 is a P type semiconductor layer, and second type semiconductor layer 133 is an N type semiconductor layer. Micro LED 100 further includes a metal layer 150 formed on a central portion of a top of N type semiconductor layer 133 and configured to connect N type semiconductor layer 133 with top conductive layer 140. A surface area of metal layer 150 is smaller than a top surface area of N type semiconductor layer 133. In some embodiments, a ratio of the surface area of metal layer 150 and the top surface area of N type semiconductor layer 133 is not greater than 0.5.

In some embodiments, metal layer 150 is a semi-transparent layer. For example, a material of metal layer 150 is AuGe.

As shown in FIG. 1, in this example, sidewalls of first type semiconductor layer 131 (i.e., P type semiconductor layer) and light emitting layer 132 are inclined. That is, the sidewalls of first type semiconductor layer 131 and light emitting layer 132 are formed along a straight line, and an inclined angle θ is formed between the straight line and a bottom of first type semiconductor layer 131. In some embodiments, the inclined angle θ of the sidewall is from 55 degrees and 65 degrees. Accordingly, a top surface area of light emitting layer 132 is smaller than a top surface area of first type semiconductor layer 131. In some embodiments, a cross section of a top surface of micro LED 100 is a circular, and a diameter of light emitting layer 132 is smaller than a diameter of first type semiconductor layer 131. Accordingly, micro LED 100 has a tapered mesa structure.

Still referring to FIG. 1, in some embodiments, bonding layer 120 includes a metal bonding layer 121 provided on IC backplane 110, and a transparent bonding layer 122 formed on metal bonding layer 121. Transparent bonding layer 122 is bonded with first type semiconductor layer 131 (i.e., P type semiconductor layer), and bonded with metal bonding layer 121. In some embodiments, transparent bonding layer 122 is a TCO (transparent conductive oxide) layer, for example, an ITO (Indium Tin Oxide) layer, an AZO (Antimony doped Zinc Oxide) layer, an ATO (Antimony doped Tin Oxide) layer, an FTO (Fluorine doped Tin Oxide) layer, a CdO (Cadmium Oxide) layer, a GZO (Gallium doped Zinc Oxide) layer, IGZO (Indium Gallium Zinc Oxide) layer, or the like. IC backplane 110 includes a bottom pad 111 electrically connected to metal bonding layer 121.

In some embodiments, a top section of micro LED 100 has a circular cross section, and a diameter of a bottom surface of micro LED 100 is less than 5 μm.

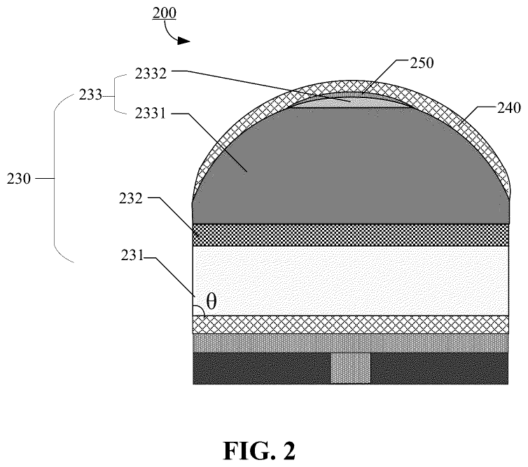

FIG. 2 illustrates a structural diagram showing a micro LED 200 that is a variant of micro LED 100 shown in FIG. 1, according to some embodiments of the present disclosure. Micro LED 200 includes a first type semiconductor layer 231, a light emitting layer 232 formed on the first type semiconductor layer 231, and a second type semiconductor layer 233 formed on light emitting layer 232. Consistent with micro LED 100, first type semiconductor layer is a P type semiconductor layer and second type semiconductor layer is an N type semiconductor layer. As shown in FIG. 2, sidewalls of first type semiconductor layer 231 (i.e., P type semiconductor layer) and light emitting layer 232 are formed along a straight line and almost vertical as viewed in FIG. 2. In some embodiments, an inclined angle θ formed between the straight line and a bottom of first type semiconductor layer 231 is greater than 85 degrees, for example, from 85 degrees and 90 degrees. Accordingly, micro LED 200 has a vertical mesa structure, which can increase beam angle performance.

In some embodiments, N type semiconductor layer 233 includes an N type cladding layer 2331 and a doped N type contact layer 2332. N type cladding layer 2331 is formed on light emitting layer 232 and doped N type contact layer 2332 is formed on a central portion of a top of N type cladding layer 2331. A ratio between a thickness of doped N type contact layer 2332 and a thickness of N type cladding layer 2331 is from 1/50 to 1/10. A metal layer 250 is further provided on a top surface of doped N type contact layer 2332. For example, metal layer 250 covers the entire top surface of doped N type contact layer 2332.

In some embodiments, materials of doped N type contact layer 2332 is n-GaAs, n-AlInP, or n-(Al) (In) (Ga) P.

Description of other features of micro LED 200 may be found by referring to corresponding features described above with reference to FIG. 1, which will not be repeated here.

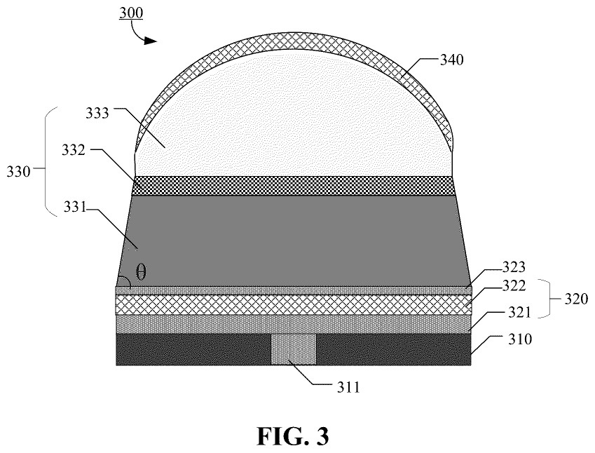

FIG. 3 illustrates a structural diagram showing an exemplary micro LED 300, according to some embodiments of the present disclosure. As shown in FIG. 3, micro LED 300 includes a P-N structure 330 formed on an IC backplane 310. P-N structure 330 includes a first type semiconductor layer 331, a light emitting layer 332 formed on first type semiconductor layer 331, and a second type semiconductor layer 333 formed on light emitting layer 332. Micro LED 300 further includes a top conductive layer 340 formed on a top surface of P-N structure 330. In this example, first type semiconductor layer 331 is an N type semiconductor layer and second type semiconductor layer 333 is a P type semiconductor layer. Second type semiconductor layer 333 (i.e., the P type semiconductor layer) can be bonded with top conductive layer 340 directly.

Micro LED 300 further includes a bonding layer 320 including a first metal bonding layer 321, a transparent bonding layer 322, and a second metal bonding layer 323 from bottom to top. First metal bonding layer 321 and second metal bonding layer 323 are made of metal, which is conductive and non-transparent. In some embodiments, transparent bonding layer 322 is a TCO (transparent conductive oxide) thin film, for example, an ITO (Indium Tin Oxide) film, an AZO (Antimony doped Zinc Oxide) film, an ATO (Antimony doped Tin Oxide) film, an FTO (Fluorine doped Tin Oxide) film, or the like. N type semiconductor layer 331 is bonded with second metal bonding layer 323, second metal bonding layer 323 is bonded with transparent bonding layer 322, and transparent bonding layer 322 is bonded with first metal bonding layer 321. IC backplane 310 includes a bottom pad 311 electrically connected to first metal bonding layer 321. In this example, second type semiconductor layer 333 has a spherical cap structure, i.e., P type semiconductor layer has a spherical cap structure.

As shown in FIG. 3, in this example, sidewalls of first type semiconductor layer 331 (i.e., N type semiconductor layer) and light emitting layer 332 are inclined. That is, the sidewalls of first type semiconductor layer 331 and light emitting layer 332 are formed along a straight line, and an inclined angle θ is formed between the straight line and a bottom of first type semiconductor layer 331. In some embodiments, the inclined angle θ of the sidewall is from 55 degrees and 65 degrees. Description of other features of micro LED 300 may be found by referring to corresponding features described above with reference to FIG. 1, which will not be repeated here.

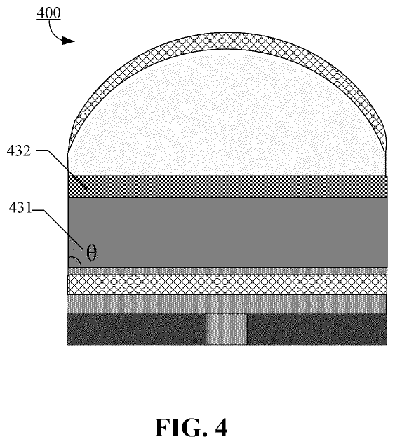

FIG. 4 illustrates a structural diagram showing a micro LED 400 that is a variant of micro LED 300 shown in FIG. 3, according to some embodiments of the present disclosure. Micro LED 400 includes a first type semiconductor layer 431 and a light emitting layer 432 formed on first type semiconductor layer 431. As shown in FIG. 4, sidewalls of first type semiconductor layer 431 (i.e., an N type semiconductor layer) and light emitting layer 432 are formed along a straight line and almost vertical as viewed in FIG. 4. In some embodiments, an inclined angle θ formed between the straight line and a bottom of first type semiconductor layer 431 is greater than 85 degrees, for example, from 85 degrees and 90 degrees. Accordingly, micro LED 400 has a vertical mesa structure, which can increase beam angle performance.

Description of other features of micro LED 400 may be found by referring to corresponding features described above with reference to FIG. 3, which will not be repeated here.

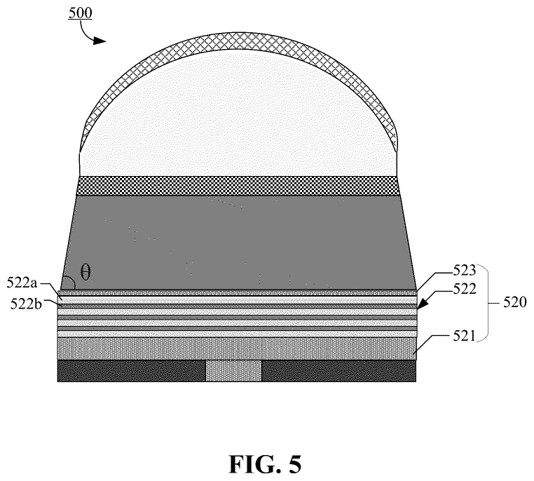

FIG. 5 illustrates a structural diagram showing a micro LED 500 that is another variant of micro LED 300 shown in FIG. 3, according to some embodiments of the present disclosure. As shown in FIG. 5, micro LED 500 includes a bonding layer 520 that comprises a transparent bonding layer 522 as a distributed Bragg reflection (DBR) layer formed between a first metal bonding layer 521 and a second metal bonding layer 523. The DBR layer includes a plurality of sputtered transparent bonding layers 522a and a plurality of porous transparent bonding layers 522b. The plurality of sputtered transparent bonding layers 522a and the plurality of porous transparent bonding layers 522b are alternately layered. For example, in some embodiments, a first one of sputtered transparent bonding layers 522a is formed on first metal bonding layer 521, a first one of porous transparent bonding layers 522b is formed on the first one of sputtered transparent bonding layers 522a, a second one of sputtered transparent bonding layers 522a is formed on the first one of porous transparent bonding layers 522b, a second one of porous transparent bonding layers 522b is formed on the second one of sputtered transparent bonding layers 522a, a third one of sputtered transparent bonding layers 522a is formed on the second one of porous transparent bonding layers 522b, a third one of porous transparent bonding layers 522b is formed on the third one of sputtered transparent bonding layers 522a, a fourth one of sputtered transparent bonding layers 522a is formed on the third one of porous transparent bonding layers 522b, and second metal bonding layer 523 is formed on the fourth one of sputtered transparent bonding layers 522a. A number of sputtered transparent bonding layers 522a can be set equal to a number of porous transparent bonding layers 522b plus one, therefore, both first metal bonding layer 521 and second metal bonding layer 523 are bonded with one of the sputtered transparent bonding layers 522a. In some embodiments, the number of sputtered transparent bonding layers 522a could be equal to the number of porous transparent bonding layers 522b. In such case, first metal bonding layer 521 and second metal bonding layer 523 may be bonded with a sputtered transparent bonding layer or a porous transparent bonding layer. In some embodiments, the number of sputtered transparent bonding layers 522a can be set equal to a number of porous transparent bonding layers 522b minus one, therefore, both first metal bonding layer 521 and second metal bonding layer 523 are bonded with one of the porous transparent bonding layers 522b. Accordingly, it can be understood that the number of sputtered transparent bonding layers 522a and the number of porous transparent bonding layers 522b are not limited herein, and can be varied according to actual practice.

In some embodiments, a refractive index of each of sputtered transparent bonding layers 522a is greater than 1.7, for example, 1.9, and a refractive index of each of porous transparent bonding layers 522b is less than 1.5. In some embodiments, the sputtered transparent bonding layers 522a and porous transparent bonding layers 522b are TCO thin films, for example, one or more of an ITO film, an AZO film, an ATO film, an FTO film, or the like.

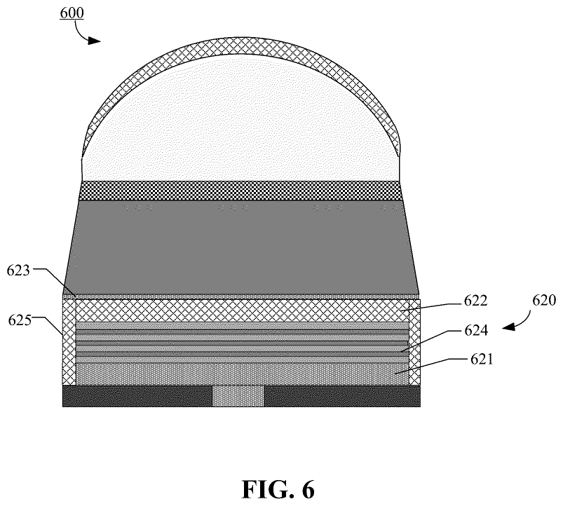

FIG. 6 illustrates a structural diagram showing a micro LED 600 that is another variant of micro LED 300 shown in FIG. 3, according to some embodiments of the present disclosure. As shown in FIG. 6, a bonding layer 620 of micro LED 600 includes a second metal bonding layer 623 formed on a transparent bonding layer 622, and a dielectric distributed Bragg reflection (DBR) layer 624 between transparent bonding layer 622 and a first metal bonding layer 621. A side conductive structure 625 is provided surrounding DBR layer 624 for connecting transparent bonding layer 622 with first metal bonding layer 621. In some embodiments, dielectric DBR layer 624 is formed by a plurality of SiO₂ layers and a plurality of SiNx layers, with the plurality of SiO₂ layers and the plurality of SiNx layers being alternately layered. In some embodiments, a refractive index of each SiO₂ layer is 1.45, and a refractive index of each SiNx layer is 2.1. In some embodiments, carriers are injected via side conductive structure 625. Therefore, a current path is formed between transparent bonding layer 622 and first metal bonding layer 621.

Description of other features of micro LED 500 and micro LED 600 may be found by referring to corresponding features described above with reference to FIG. 3, which will not be repeated here.

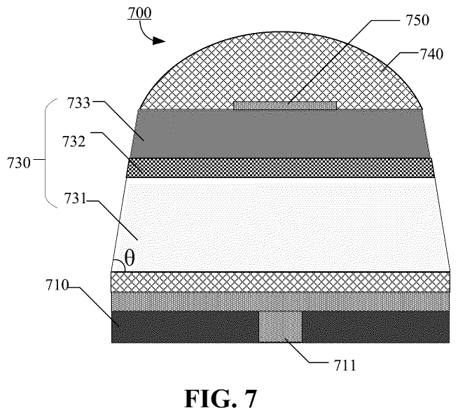

FIG. 7 illustrates a structural diagram showing an exemplary micro LED 700, according to some embodiments of the present disclosure. As shown in FIG. 7, micro LED 700 includes a P-N structure 730 provided on an IC backplane 710, and a bonding layer 720 provided between P-N structure 730 and IC backplane 710. P-N structure 730 includes a first type semiconductor layer 731, a light emitting layer 732 formed on the first type semiconductor layer 731, and a second type semiconductor layer 733 formed on light emitting layer 732. A top surface of P-N structure 730 is flat. Micro LED 700 further includes a top conductive layer 740 formed on the top surface of P-N structure 730. As shown in FIG. 7, top conductive layer 740 has a spherical cap structure. Top conductive layer 740 is a TCO (transparent conductive oxide) layer, for example, an ITO (Indium Tin Oxide) layer, an AZO (Antimony doped Zinc Oxide) layer, an ATO (Antimony doped Tin Oxide) layer, an FTO (Fluorine doped Tin Oxide) layer, a CdO (Cadmium Oxide) layer, or a GZO (Gallium doped Zinc Oxide).

In this example, first type semiconductor layer 731 is a P type semiconductor layer and second type semiconductor layer 733 is an N type semiconductor layer. Micro LED 700 further includes a metal layer 750 formed between top conductive layer 740 and second type semiconductor layer 733 (i.e., N type semiconductor layer) for providing ohmic contact.

As shown in FIG. 7, a sidewall of P-N structure 730 is inclined. That is, sidewalls of first type semiconductor layer 731, light emitting layer 732, and second type semiconductor layer 733 are formed along a straight line, and an inclined angle θ is formed between the straight line and a bottom of first type semiconductor layer 731. In some embodiments, the inclined angle θ of the sidewall is from 55 degrees and 65 degrees. In some embodiments, a sidewall of P-N structure 730 is almost vertical, for example, an inclined angle θ of the sidewall is greater than 85 degrees.

Description of other features of micro LED 700 may be found by referring to corresponding features described above with reference to FIG. 1, which will not be repeated here.

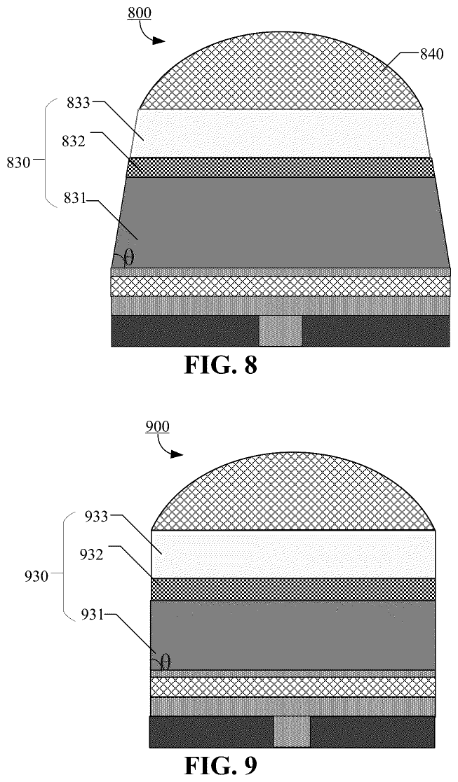

FIG. 8 illustrates a structural diagram showing an exemplary micro LED 800, according to some embodiments of the present disclosure. As shown in FIG. 8, a P-N structure 830 of micro LED 800 includes a first type semiconductor layer 831, a light emitting layer 832 formed on first type semiconductor layer 831, and a second type semiconductor layer 833 formed on light emitting layer 832. First type semiconductor layer 831 is an N type semiconductor layer and a second type semiconductor layer 833 is a P type semiconductor layer. A top conductive layer 840 formed on second type semiconductor layer 833 has a spherical cap structure. A sidewall of P-N structure 830 is inclined. That is, sidewalls of first type semiconductor layer 831, light emitting layer 832, and second type semiconductor layer 833 are formed along a straight line, and an inclined angle θ is formed between the straight line and a bottom of first type semiconductor layer 831. In some embodiments, the inclined angle θ of the sidewall is from 55 degrees and 65 degrees.

FIG. 9 illustrates a structural diagram showing a micro LED 900 that is a variant of micro LED 800 shown in FIG. 8, according to some embodiments of the present disclosure. As shown in FIG. 10, a P-N structure 930 of micro LED 900 includes a first type semiconductor layer 931, a light emitting layer 932 formed on first type semiconductor layer 931, and a second type semiconductor layer 933 formed on light emitting layer 932. Sidewalls of P-N structure 930 (i.e., sidewalls of first type semiconductor layer 931, light emitting layer 932, and second type semiconductor layer 933) are formed along a straight line and almost vertical as viewed in FIG. 9. In some embodiments, an inclined angle θ formed between the straight line and a bottom of first type semiconductor layer 931 is greater than 85 degrees, for example, from 85 degrees and 90 degrees. Accordingly, micro LED 900 has a vertical mesa structure, which can increase beam angle performance.

Description of other features of micro LED 800 and micro LED 900 may be found by referring to corresponding features described above with reference to FIG. 3, which will not be repeated here.

FIG. 10 illustrates a structural diagram showing a top view of an exemplary micro LED display panel 1000, according to some embodiments of the present disclosure. Referring to FIG. 10, micro LED display panel 1000 includes a micro LED array 1010 and an IC (integrated circuit) backplane 1020. Micro LED array 1010 is located on IC backplane 1020 to form an image display area of micro LED display panel 1000. The rest of the area on IC backplane 1020 not covered by micro LED array 1010 is formed as a non-functional, i.e., non-display, area. IC backplane 1020 is formed at the back surface of micro LED array 1010 with a part extending outside of, i.e., not covered by, micro LED array 1010. Micro LED array 1010 includes a plurality of micro LEDs 1011 provided in an array. IC backplane 1020 is configured to control the plurality of micro LEDs 1011. IC backplane 1020 may include a bottom pad array (not shown) corresponding to micro LED array 1010. The bottom pad array includes a plurality of conductive bottom pads (for example, bottom pad 111 in FIG. 1 and bottom pad 311 in FIG. 3), and one bottom pad corresponds to one micro LED 1011. One micro LED 1011 of the plurality of micro LEDs 1011 is electrically connected with one bottom pad of the plurality of bottom pads.

Each micro LED herein (e.g., micro LEDs 100 to 900) has a very small volume. The micro LED can be applied in a micro LED display panel. The light emitting area of the micro LED display panel, e.g., micro LED display panel 1000, is very small, such as 1 mm×1 mm, 3 mm×5 mm, etc. In some embodiments, the light emitting area is the area of the micro LED array in the micro LED display panel. The micro LED display panel includes one or more micro LEDs that form a pixel array in which the micro LEDs are pixels, such as a 1600×1200, 680×480, or 1920×1080-pixel array. The diameter of each micro LED is in the range of about 200 nm to 2 μm. An IC backplane, e.g., IC backplane 1020, is formed at the back surface of micro LED array 1010 and is electrically connected with micro LED array 1010. The IC backplane acquires signals such as image data from outside via signal lines to control corresponding micro LEDs to emit light or not.

It is understood by those skilled in the art that the micro LED display panel is not limited by the structure described above, and may include greater or fewer components than those illustrated, or some components may be combined, or a different component may be utilized.

It should be noted that relational terms herein such as “first” and “second” are used only to differentiate an entity or operation from another entity or operation, and do not require or imply any actual relationship or sequence between these entities or operations. Moreover, the words “comprising,” “having,” “containing,” and “including,” and other similar forms are intended to be equivalent in meaning and be open ended in that an item or items following any one of these words is not meant to be an exhaustive listing of such item or items, or meant to be limited to only the listed item or items.

As used herein, unless specifically stated otherwise, the term “or” encompasses all possible combinations, except where infeasible. For example, if it is stated that a database may include A or B, then, unless specifically stated otherwise or infeasible, the database may include A, or B, or A and B. As a second example, if it is stated that a database may include A, B, or C, then, unless specifically stated otherwise or infeasible, the database may include A, or B, or C, or A and B, or A and C, or B and C, or A and B and C.

In the foregoing specification, embodiments have been described with reference to numerous specific details that can vary from implementation to implementation. Certain adaptations and modifications of the described embodiments can be made. Other embodiments can be apparent to those skilled in the art from consideration of the specification and practice of the invention disclosed herein. It is intended that the specification and examples be considered as exemplary only, with a true scope and spirit of the invention being indicated by the following claims. It is also intended that the sequence of steps shown in figures are only for illustrative purposes and are not intended to be limited to any particular sequence of steps. As such, those skilled in the art can appreciate that these steps can be performed in a different order while implementing the same method.

In the drawings and specification, there have been disclosed exemplary embodiments. However, many variations and modifications can be made to these embodiments. Accordingly, although specific terms are employed, they are used in a generic and descriptive sense only and not for purposes of limitation.

What is claimed is:

1. A micro LED comprising:
a bonding layer;
a P-N structure formed on the bonding layer, wherein the P-N structure includes a first type semiconductor layer, a light emitting layer formed on the first type semiconductor layer, and a second type semiconductor layer formed on the light emitting layer; and
a top conductive layer formed on the P-N structure, wherein a top surface of the micro LED is a curved surface.

2. The micro LED according to claim 1, wherein the top surface of the micro LED is a dome.

3. The micro LED according to claim 1, wherein the second type semiconductor layer has a spherical cap structure.

4. The micro LED according to claim 3, wherein the second type semiconductor layer comprises:
a base portion formed on the light emitting layer, wherein a sidewall of the base portion is vertical; and
a curved portion formed on the base portion, the base portion and the curved portion being an integrated structure.

5. The micro LED according to claim 3, wherein the first type semiconductor layer is a P type semiconductor layer and the second type semiconductor layer is an N type semiconductor layer, the micro LED further comprises:
a metal layer formed on a top of the N type semiconductor layer and configured to connect the N type semiconductor layer with the top conductive layer.

6. The micro LED according to claim 5, wherein the metal layer is a semi-transparent layer.

7. The micro LED according to claim 6, wherein a material of the metal layer is AuGe.

8. The micro LED according to claim 3, wherein the first semiconductor layer is an N type semiconductor layer and the second semiconductor layer is a P type semiconductor layer.

9. The micro LED according to claim 8, wherein the bonding layer comprises a first metal bonding layer, a transparent bonding layer, and a second metal bonding layer from bottom to top.

10. The micro LED according to claim 9, wherein the transparent bonding layer comprises a plurality of sputtered transparent bonding layers and a plurality of porous transparent bonding layers, the plurality of sputtered transparent bonding layers and the plurality of porous transparent bonding layers being alternated layered.

11. The micro LED according to claim 9, wherein the bonding layer further comprises:
a dielectric distributed Bragg reflection (DBR) layer between the transparent bonding layer and the first metal bonding layer; and
a side conductive structure provided on a side of the DBR layer for connecting the transparent bonding layer with the first metal bonding layer.

12. The micro LED according to claim 1, wherein the top conductive layer has a spherical cap structure.

13. The micro LED according to claim 1, wherein an inclined angle of a sidewall of the P-N structure is greater than 85 degrees.

14. The micro LED according to claim 13, wherein the sidewall of the P-N structure is vertical.

15. A micro LED display panel, comprising:
an integrated circuit (IC) backplane comprising a bottom pad array, the bottom pad array comprising a plurality of bottom pads; and
a micro LED array formed on the IC backplane, the micro LED array comprising a plurality of micro LEDs;
wherein one micro LED of the plurality of micro LEDs is electrically connected with one bottom pad of the plurality of bottom pads; and each of the plurality of micro LEDs comprises:
a bonding layer;
a P-N structure formed on the bonding layer, wherein the P-N structure includes a first type semiconductor layer, a light emitting layer formed on the first type semiconductor layer, and a second type semiconductor layer formed on the light emitting layer; and
a top conductive layer formed on the P-N structure, wherein a top surface of the micro LED is a curved surface.

16. The micro LED display panel according to claim 15, wherein the top surface of the micro LED is a dome.

17. The micro LED display panel according to claim 15, wherein the second type semiconductor layer has a spherical cap structure.

18. The micro LED display panel according to claim 17, wherein the second type semiconductor layer comprises:
a base portion formed on the light emitting layer, wherein a sidewall of the base portion is vertical; and
a curved portion formed on the base portion, the base portion and the curved portion being an integrated structure.

19. The micro LED display panel according to claim 15, wherein the top conductive layer has a spherical cap structure.

20. The micro LED display panel according to claim 15, wherein an inclined angle of a sidewall of the P-N structure is greater than 85 degrees.
